(19) United States
(12) Patent Application Publication
(10) Pub. No.: US 2007/0070687 A1
(43) Pub. Date: Mar. 29, 2007

(54) Adjustable Current Source for an MRAM Circuit

(75) Inventors: Kuang-Lun Chen, St. Paul, MN (US); James Chyi Lai, St. Paul, MN (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: NORTHERN LIGHTS SEMICONDUCTOR CORP., St. Paul, MN (US)

(21) Appl. No.: 11/530,592

(22) Filed: Sep. 11, 2006

Related U.S. Application Data
(60) Provisional application No. 60/716,357, filed on Sep. 12, 2005.

(51) Int. Cl. G11C 11/00

(52) U.S. Cl. 365/158

(57) ABSTRACT

A word current source for a magnetoresistive random access memory (MRAM) circuit includes an n-channel transistor including a gate, a source and a drain, where the source is coupled to a supply ground, and the drain is coupled to the MRAM circuit. A positive supply voltage is coupled to the MRAM circuit so as to allow current to flow through the MRAM circuit when an activation signal is applied to the gate by a control circuit.

### CROSS-REFERENCE TO RELATED APPLICATION

This application claims the priority benefit of U.S. Provisional Application Ser. No. 60/716,357, filed Sep. 12, 2005, the full disclosures of which are incorporated herein by reference.

### BACKGROUND

1. Field of Invention

The present invention relates to magnetoresistive random access memory (MRAM) devices, and, more particularly, to a word current source configuration and control for an MRAM circuit using an n-channel semiconductor device.

2. Description of Related Art

In magnetoresistive random access memory (MRAM) designs, word current sources are needed to provide large currents while operating with short turn on and turn off times. Since every memory element is associated with two such word current sources, tho word current sources are replicated and present in many places throughout a typical MRAM. As a result, a sizable area of an MRAM chip is consumed by the numerous word current sources. Word current sources in complementary metal oxide semiconductor (CMOS) circuits are conventionally constructed using p-channel transistors, where the p-channel transistors are typically connected to a chip's positive voltage supply. The positive voltage supply is conventionally considered to be a current input.

Referring now to FIG. 1, there shown is a schematic circuit diagram of an MRAM system 5 using a prior art word current source constructed using a conventional p-channel transistor device. The MRAM system 5 includes a positive voltage supply (VDD), a supply ground (GND), a p-channel control circuit 10, an MRAM circuit 20 supplied by the regulated current source and a p-channel transistor 30. The p-channel transistor 30 includes a gate (Gp), a drain (Dp) and a source (Sp). The gate (Gp) is connected to the output 12 of the p-channel control circuit 10, and the drain (Dp) is connected to a current input 22 of the MRAM circuit 20. The source (Sp) is connected to the positive voltage supply (VDD). When an activation signal is applied to gate (Gp), current I flows into the MRAM circuit 20 that then releases the current I into the supply ground (GND). In this case, the p-channel control circuit 10 regulates the voltage level of p-channel control and limits the amount of current fed through it and the other components. The p-channel control circuit 10 also regulates the current when the p-channel transistor and hence the source itself is turned on and off. A feed back amplifier is used to accomplish this function.

Control while switching the p-channel transistor 30 on and off is also important because the p-channel transistor 30 is turned on and off rapidly. Rapid cycling between on and off conditions could lead to a brief period where the current exceeds the desired level. This is a condition known as switching overshoot. In the MRAM, currents exceeding the desired level for only a brief time could cause faulty operation. Thus, word current sources must be closely controlled so that there is very little switching overshoot.

### SUMMARY

According to one embodiment of the present invention, a word current source for a magnetoresistive random access memory (MRAM) circuit is provided. The word current source includes an n-channel transistor including a gate, a source and a drain, where the source is coupled to a supply ground, and the drain is coupled to the MRAM circuit. A positive supply voltage is coupled to the MRAM circuit so as to allow current to flow through the MRAM circuit when an activation signal is applied to the gate by a control circuit.

It is to be understood that both the foregoing general description and the following detailed description are examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a schematic circuit diagram of a prior art word current source for use in a magnetoresistive random access memory (MRAM) using a conventional p-channel device; and

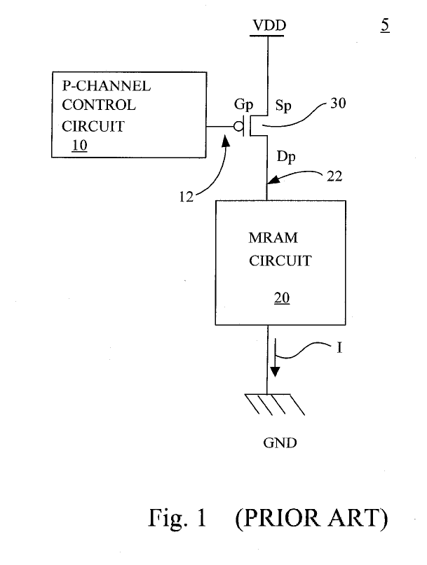

FIG. 2 is a schematic circuit diagram of a word current source for use in an MRAM using an n-channel semiconductor device constructed in accordance with one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Channel devices have less capacitance and can be turned on in less time, with greater control. This in turn is expected to lead to lower noise during operation, thereby increasing the reliability of an MRAM constructed in accordance with embodiments of the present invention.

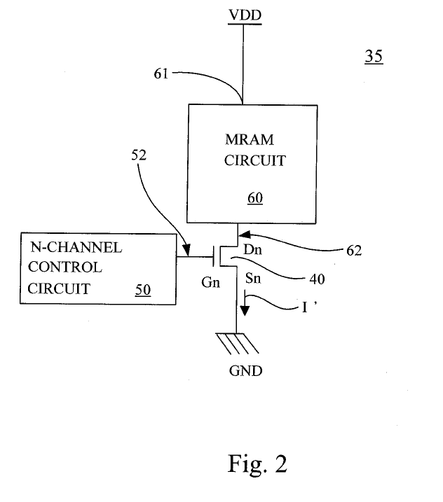

Referring now to FIG. 2, there shown is a schematic circuit diagram of a magnetoresistive random access memory (MRAM) system 35 using a word current source constructed using an n-channel semiconductor device according to one embodiment of the present invention. The MRAM system 35 includes a positive voltage supply (VDD), a supply ground (GND), n-channel control circuit 50, an MRAM circuit 60 supplied by the regulated current source and an n-channel semiconductor device 40. The positive voltage supply (VDD) is connected to a current input 61 of the MRAM circuit 60. The n-channel semiconductor device 40 includes a gate (Gn), a drain (Dn) and a source (Sn). The gate (Gn) is connected to the output 52 of the n-channel control circuit 50, and the drain (Dn) is connected to a current output 62 of the MRAM circuit 60. The source (Sn) is connected to the supply ground (GND). When an activation signal is applied to the gate (Gn), current I flows into the MRAM circuit 60 and through the n-channel semiconductor device 40 into the supply ground (GND). In this case, the n-channel control circuit 50 regulates the voltage level of n-channel control and limits the amount of current fed through it and the other components. The n-channel control circuit 50 also regulates the current when the n-channel semiconductor device and hence the source itself is turned on and off. A feed back amplifier may be used to accomplish this function.

In one embodiment, the MRAM circuit 60 may include any useful MRAM memory circuit, as for example, a word line, or a byte line. The n-channel semiconductor device may be an n-channel transistor, or may be an n-channel complementary metal oxide semiconductor (CMOS) transistor. The activation signal may has a voltage level of at least a logic “1” in order to turn on the n-channel semiconductor device. Voltage levels between logic “1” and logic “0” may be used to control current flow through the n-channel semiconductor device.

In contrast to the prior art, the embodiment of the present invention employs word current sources constructed using n-channel semiconductor devices, such as n-channel transistors, instead of p-channel transistors. N-channel transistors conduct more current per unit size than p-channel transistors and can be more precisely controlled. Thus, the size of the drive transistor can be reduced by approximately ½ as compared to the p-channel transistor, while maintaining tight control of the current source. Word current sources thus constructed in accordance with the embodiment are proportionally reduced in size, resulting in a substantial reduction in size for an MRAM chip employing the word current sources as contemplated by the embodiment.

The invention has been described herein in considerable detail in order to comply with the Patent Statutes and to provide those skilled in the art with the information needed to apply the novel principles of the present invention, and to construct and use such exemplary and specialized components as are required. However, it is to be understood that the invention may be carried out by specifically different equipment and devices, and that various modifications, both as to the equipment details and operating procedures, may be accomplished without departing from the true spirit and scope of the present invention.

What is claimed is:

1. A word current source for a magnetoresistive random access memory (MRAM) circuit comprising:
an n-channel transistor including a gate, a source and a drain, where the source is coupled to a supply ground, and the drain is coupled to the MRAM circuit; and
a positive supply voltage, coupled to the MRAM circuit so as to allow current to flow through the MRAM circuit when an activation signal is applied to the gate.

2. The word current source of claim 1, further comprising:
a control circuit coupled to the gate and arranged to generate the activation signal.

3. The word current source of claim 2, wherein the control circuit comprises:
means for regulating the voltage level at the gate, so as to limit the amount of current flowing through the n-channel transistor and the MRAM circuit.

4. The word current source of claim 3, wherein the means for regulating the current comprises a feed back amplifier.

5. The word current source of claim 1, wherein the n-channel transistor comprises an n-channel complementary metal oxide semiconductor (CMOS) transistor.

6. The word current source of claim 5, wherein the control circuit comprises:
means for regulating the current flowing through the n-channel CMOS transistor when the n-channel CMOS transistor is turned on and off.

7. A word current source for a magnetoresistive random access memory (MRAM) circuit comprising:
an n-channel complementary metal oxide semiconductor (CMOS) transistor including a gate, a source and a drain, where the source is coupled to a supply ground, and the drain is coupled to the MRAM circuit;
a positive supply voltage, coupled to the MRAM circuit so as to allow current to flow through the MRAM circuit when an activation signal is applied to the gate; and
a control circuit arranged to generate the activation signal, wherein the control circuit comprises means for regulating the voltage level at the gate, so as to limit the amount of current flowing through the n-channel CMOS transistor and the MRAM circuit.

8. The word current source of claim 7, wherein the means for regulating the current comprises a feed back amplifier.

9. The word current source of claim 7, wherein the control circuit comprises means for regulating the current flowing through the n-channel CMOS transistor when the n-channel CMOS transistor is turned on and off.

10. A word current source for a magnetoresistive random access memory (MRAM) circuit comprising:
an n-channel semiconductor device including a first terminal, a second terminal and a third terminal, where the first terminal is coupled to a supply ground, and the second terminal is coupled to the MRAM circuit; and
a positive supply voltage, coupled to the MRAM circuit so as to allow current to flow through the MRAM circuit when an activation signal is applied to the third terminal.

11. The word current source of claim 10, further comprising:
a control circuit coupled to the third terminal and arranged to generate the activation signal.

12. The word current source of claim 11, wherein the control circuit comprises means for regulating the voltage level at the third terminal, so as to limit the amount of current flowing through the n-channel semiconductor device and the MRAM circuit.

13. The word current source of claim 12, wherein the means for regulating the current comprises a feed back circuit.
